(19) United States
(12) Patent Application Publication
(10) Pub. No.: US 2005/0263856 A1
(43) Pub. Date: Dec. 1, 2005

(54) Semiconductor device and method of fabricating the same

(75) Inventors: Naoya Sotani, Kobe-shi (JP); Isao Hasegawa, Gifu-shi (JP); Daisuke Ide, Kobe-shi (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/138,502

(22) Filed: May 27, 2005

(30) Foreign Application Priority Data
May 28, 2004 (JP) JP2004-159790

(51) Int. Cl. H01L 29/04

(52) U.S. Cl. 257/627

(57) ABSTRACT

Provided is a semiconductor device capable of improving the characteristics of a plurality of semiconductor elements formed on a substrate while uniformizing the characteristics. This semiconductor device comprises a substrate and a plurality of semiconductor elements, formed on the substrate, each including a semiconductor layer having a channel region with carriers flowing in a first direction. The semiconductor layer constituting each of the plurality of semiconductor elements has a twin plane, and the twin plane is formed to extend in such a second direction that the carriers flowing through the channel region hardly traverse the twin plane.

### BACKGROUND OF THE INVENTION

1. Field of the Invention

The present invention relates to a semiconductor device and a method of fabricating the same, and more particularly, it relates to a semiconductor device comprising a plurality of semiconductor elements including a semiconductor layer and a method of fabricating the same.

2. Description of the Background Art

In general, a plurality of thin-film transistors (TFTs) employed for a pixel portion, a peripheral circuit etc. are formed on a substrate in a liquid-crystal display or an organic EL display. In recent years, polycrystalline silicon films have been employed as active layers of such thin-film transistors. In the liquid crystal display or the organic EL display, the characteristics such as carrier mobility of the thin-film transistors must be improved and uniformized for the purpose of sophistication, weight saving and compactification. In order to sophisticate the thin-film transistors including the active layers of polycrystalline silicon films and uniformize the characteristics thereof, the polycrystalline silicon films formed on s substrate must be rendered as close to a single-crystalline state as possible. Particularly in the organic EL display, the thin-film transistors of the pixel portion are employed not for switching but for adjusting current supplied to organic EL elements, and hence the characteristics of the thin-film transistors remarkably influence the picture quality.

The polycrystalline silicon films may be rendered close to a single-crystalline state by forming the polycrystalline silicon films to have large crystal grain sizes or position-controlling the polycrystalline silicon films for forming portions having large crystal grain sizes on active regions. According to still another method, the crystal orientations of the polycrystalline silicon films are regulated by controlling film forming conditions, crystallizing conditions etc., as disclosed in Japanese Patent Laying-Open Nos. 58-84464 (1983) and 63-307431 (1988), for example. The aforementioned Japanese Patent Laying-Open No. 58-84464 discloses a method of regulating the crystal orientations of polycrystalline silicon films in a direction perpendicular to the main surface of a substrate by controlling sputtering conditions when forming the polycrystalline silicon films by sputtering. The aforementioned Japanese Patent Laying-Open No. 63-307431 discloses a method of regulating the crystal orientations of polycrystalline silicon films in a direction perpendicular to the main surface of a substrate by controlling a heat treatment temperature for crystallization in crystallization of the polycrystalline silicon films.

In each of the aforementioned Japanese Patent Laying-Open Nos. 58-84464 and 63-307431, however, the overall film temperatures are substantially equalized with each other in formation of the polycrystalline silicon films with no anisotropy in the direction parallel to the main surface of the substrate, and hence it is disadvantageously difficult to regulate the crystal orientations in this direction. In order to regulate the crystal orientations of the polycrystalline silicon films in the direction parallel to the main surface of the substrate, for example, it is necessary to cause temperature gradients in the direction of the silicon films parallel to the main surface while growing crystals from high-temperature regions toward low-temperature regions. According to each of the aforementioned Japanese Patent Laying-Open Nos. 58-84464 and 63-307431 substantially equalizing the overall film temperatures with each other in formation of the polycrystalline silicon films, however, no anisotropy such as temperature gradients is present in the direction parallel to the main surface of the substrate, and hence it is difficult to regulate the crystal orientations of the polycrystalline silicon films in the direction parallel to the main surface of the substrate.

When the crystal orientations of the polycrystalline silicon films are not regulated in the direction parallel to the main surface of the substrate as described above, extensional directions of twin planes, which are defects formed on the polycrystalline silicon films, are disadvantageously remarkably dispersed. Twins are crystals identical in crystal lattice structure to each other in a single crystal grain mirror-symmetrical with respect to a constant boundary surface referred to as a twin plane. Remarkable dispersion of the extensional directions of the twin planes results in such a problem that, even if a channel region of a certain thin-film transistor (thin-film semiconductor element) is so formed that no carriers traverse twin planes, a channel region of another thin-film transistor (thin-film semiconductor element) provided on another region may disadvantageously be so formed that carriers traverse twin planes. When the channel region is so formed that the carriers traverse the twin planes, carrier mobility is reduced due to the carriers flowing through the channel region to traverse the twin planes, and hence the characteristics of the thin-film transistor including a polycrystalline silicon film formed with the twin planes are disadvantageously deteriorated. Further, the thin-film transistor including the polycrystalline silicon film formed with the twin planes disadvantageously remarkably differs in carrier mobility from a thin-film transistor including a polycrystalline silicon film formed with no twin planes. Consequently, the characteristics of the plurality of thin-film transistors formed on the substrate are disadvantageously deteriorated and ununiformized.

### SUMMARY OF THE INVENTION

The present invention has been proposed in order to solve the aforementioned problems, and an object of the present invention is to provide a semiconductor device capable of improving the characteristics of a plurality of semiconductor elements formed on a substrate while uniformizing the characteristics.

Another object of the present invention is to provide a method of fabricating a semiconductor device capable of improving the characteristics of a plurality of semiconductor elements formed on a substrate while uniformizing the characteristics.

In order to attain the aforementioned objects, a semiconductor device according to a first aspect of the present invention comprises a substrate and a plurality of semiconductor elements, formed on the substrate, each including a semiconductor layer having a channel region with carriers flowing in a first direction. The semiconductor layer constituting each of the plurality of semiconductor elements has a twin plane, and the twin plane is formed to extend in such a second direction that the carriers flowing through the channel region hardly traverse the twin plane.

In the semiconductor device according to the first aspect, as hereinabove described, the semiconductor layer constituting each of the plurality of semiconductor elements is formed to have the twin plane while the twin plane is formed to extend in the second direction in which the carriers flowing through the channel region hardly traverse the twin plane so that the carriers flowing through the channel region can be inhibited from traversing the twin plane, whereby carrier mobility can be inhibited from reduction. This is because twin planes cannot intersect with each other in the same crystal grain and hence formation of a twin plane extending in a direction other than the second direction can be suppressed. Thus, the characteristics of the plurality of semiconductor elements each including the semiconductor layer formed with the twin plane can be improved. Also when the semiconductor layer formed with the twin plane and another semiconductor layer formed with no twin plane are present on the same substrate, the carriers flowing through the channel region of the semiconductor layer formed with the twin plane can be so inhibited from traversing the twin plane that the semiconductor element including the semiconductor layer formed with the twin plane can be inhibited from differing in carrier mobility from another semiconductor element including the semiconductor layer formed with no twin plane. Consequently, the plurality of semiconductor elements can be inhibited from dispersion of characteristics, whereby the characteristics can be uniformized.

In the aforementioned semiconductor device according to the first aspect, the twin plane is preferably formed to extend in a direction substantially parallel to the first direction in which the carriers flow through the channel region. According to this structure, the carriers flowing through the channel region can be easily inhibited from traversing the twin plane.

In the aforementioned semiconductor device according to the first aspect, the semiconductor layer preferably has a face-centered cubic lattice crystal structure, and a crystal orientation <u v w> in the first direction preferably satisfies the following two formulas:
|u−v−w|/(u²+v²+w²)^{1/2}≦0.3
u≧−v≧w≧0
assuming that the crystal orientation <u v w> corresponds to the first direction in which the carriers in the semiconductor layer flow through the channel region and an angle formed by a direction perpendicular to the main surface of the substrate and a crystal orientation <1 1 1> exceeds about 10°. According to this structure, deviation between the extensional direction of the twin plane formed on the semiconductor layer and the first direction in which the carriers flow through the channel region of the semiconductor layer can be set in the range of about 100, whereby the carriers flowing through the channel region can be easily inhibited from traversing the twin plane.

In the aforementioned semiconductor device according to the first aspect, the semiconductor layer preferably has a plurality of twin planes, and the plurality of twin planes are preferably formed to extend substantially in the same direction. According to this structure, carriers flowing through the channel region can be easily inhibited from traversing the twin planes by forming the channel region so that the carriers flow in the same direction as the extensional direction of the plurality of twin planes when the semiconductor layer has the plurality of twin planes.

The aforementioned semiconductor device according to the first aspect preferably further comprises an insulating film formed between the substrate and the semiconductor layer to be in contact with the semiconductor layer with a contact angle of not more than about 45° with a fused semiconductor layer. According to this structure, the fused semiconductor layer can be inhibited from aggregation and bulking in crystallization, whereby a crystallization condition for increasing the time for fusing the semiconductor layer in crystallization can be employed. Consequently, the semiconductor layer can be more stably crystallized in anisotropic crystal growth through unidirectional fusion and solidification for suppressing dispersion of the crystal orientation, whereby the extensional direction of the twin plane formed on the semiconductor layer can be inhibited from dispersion.

In the aforementioned semiconductor device according to the first aspect, the semiconductor layer preferably includes a polycrystalline silicon film. According to this structure, the characteristics of the plurality of semiconductor elements can be easily improved and uniformized in the semiconductor device comprising the plurality of semiconductor elements each including the polycrystalline silicon film having a channel region.

In the aforementioned semiconductor device according to the first aspect, the semiconductor layer preferably includes an active layer of a thin-film transistor. According to this structure, no carriers flowing through the channel region traverse the twin plane in the active layer of the thin-film transistor constituted of the semiconductor layer having the twin plane, whereby carrier mobility can be inhibited from reduction. Thus, the characteristics of the thin-film transistor including the active layer having the twin plane can be improved.

A method of fabricating a semiconductor device according to a second aspect of the present invention comprises steps of forming a semiconductor layer serving as an active layer of each of a plurality of semiconductor elements on a substrate, crystallizing the semiconductor layer to have a twin plane extending in a prescribed direction, and forming a channel region on the semiconductor layer so that carriers flowing in a channel length direction hardly traverse the twin plane extending in the prescribed direction.

In the method of fabricating a semiconductor device according to the second aspect, as hereinabove described, the semiconductor layer serving as the active layer of each of the plurality of semiconductor elements is crystallized and the channel region is thereafter formed on the semiconductor layer so that the carriers flowing through the channel length direction hardly traverse the twin plane extending in the prescribed direction, whereby the carriers flowing through the channel region can be inhibited from traversing the twin plane and hence carrier mobility can be inhibited from reduction. Thus, a semiconductor device capable of improving the characteristics of a plurality of semiconductor elements each including a semiconductor layer formed with a twin plane can be easily formed. Also when the semiconductor layer formed with the twin plane and another semiconductor layer formed with no twin plane are present on the same substrate, the carriers flowing through the channel region of the semiconductor layer formed with the twin plane can be inhibited from traversing the twin plane so that a semiconductor element including the semiconductor layer formed with the twin plane can be inhibited from differing in carrier mobility from another semiconductor element including the semiconductor layer formed with no twin plane. Consequently, the plurality of semiconductor elements can be inhibited from dispersion of characteristics, whereby a semiconductor device capable of uniformizing the characteristics can be easily formed.

In the aforementioned method of fabricating a semiconductor device according to the second aspect, the step of forming the channel region preferably includes a step of forming the channel region so that the twin plane extending in the prescribed direction and the channel length direction in which the carriers flow are substantially parallel to each other. According to this structure, the carriers flowing through the channel region can be easily inhibited from traversing the twin plane.

In the aforementioned method of fabricating a semiconductor device according to the second aspect, the step of crystallizing the semiconductor layer preferably includes a step of crystallizing the semiconductor layer so that each of a plurality of twin planes extends in the prescribed direction. According to this structure, the carriers flowing through the channel region can be easily inhibited from traversing twin planes when the semiconductor layer has a plurality of twin planes, by forming the channel region so that the carriers flow in the same direction as the prescribed direction in which each of the plurality of twin planes extends.

In the aforementioned method of fabricating a semiconductor device according to the second aspect, the step of crystallizing the semiconductor layer preferably includes a step of supplying a temperature gradient to the semiconductor layer and crystallizing the semiconductor layer from a low temperature region toward a high temperature region in the temperature gradient. According to this structure, the crystal orientation of the semiconductor layer and the extensional direction of the twin plane can be inhibited from dispersion as compared with a case of crystallizing the semiconductor layer by entirely heating the semiconductor layer in an electric furnace or the like.

In the aforementioned method of fabricating a semiconductor device according to the second aspect, the step of crystallizing the semiconductor layer preferably includes a step of crystallizing the semiconductor layer to have the twin plane extending in the prescribed direction by scanning the semiconductor layer with a laser beam thereby heating the semiconductor layer. According to this structure, the semiconductor layer can be supplied with a temperature gradient in crystallization dissimilarly to the case of entirely heating the semiconductor layer in the electric furnace or the like. Further, the crystal orientation of the semiconductor layer can be easily regulated by making crystal growth from a low temperature region toward a high temperature region in a temperature gradient. The carriers flowing through the channel region can be easily inhibited from traversing the twin plane by crystallizing the semiconductor layer so that a specific orientation of the semiconductor layer and twin planes of a plurality of crystal grains are approximately parallel to each other while forming the channel region so that the carriers flow in a direction corresponding to the specific orientation of the semiconductor layer.

In the aforementioned method of fabricating a semiconductor device including the step of crystallizing the semiconductor layer by scanning the same with the laser beam, the laser beam preferably has a rectangular shape, and the step of crystallizing the semiconductor layer preferably includes a step of crystallizing the semiconductor layer to have the twin plane extending in the prescribed direction by scanning the semiconductor layer with the laser beam in the short-side direction of the laser beam thereby heating the semiconductor layer. According to this structure, the temperature gradient in the laser beam scanning direction can be so steepened that the crystal orientation of crystals growing from a low-temperature region toward a high-temperature region and the extensional direction of the twin plane can be more effectively inhibited from dispersion.

In the aforementioned method of fabricating a semiconductor device including the step of crystallizing the semiconductor layer by scanning the same with the laser beam, the step of forming the channel region preferably includes a step of forming the channel region so that the carriers flow in a direction substantially parallel to the scanning direction of the laser beam. According to this structure, the twin plane is formed to extend in parallel with the laser beam scanning direction, whereby the carriers flowing through the channel region can be further easily inhibited from traversing the twin plane by forming the channel region so that the carriers flow in the direction substantially parallel to the laser beam scanning direction.

The aforementioned method of fabricating a semiconductor device including the step of crystallizing the semiconductor layer by scanning the same with the laser beam preferably further comprises a step of forming an absorption film on the substrate, and the step of crystallizing the semiconductor layer preferably includes a step of irradiating the absorption film with the laser beam thereby making the absorption film generate heat and crystallizing the semiconductor layer through the heat. According to this structure, a stable laser beam not absorbed by the semiconductor but absorbed by the absorption film can be so employed that the semiconductor layer can be stably heated in crystallization. Thus, the crystal orientation and the extensional direction of the twin plane can be easily inhibited from dispersion.

In the aforementioned method of fabricating a semiconductor device further comprising the step of forming the absorption film, the step of forming the absorption film may include a step of forming the absorption film between the substrate and the semiconductor layer, and the step of crystallizing the semiconductor layer may include a step of irradiating the absorption film with the laser beam from the side of the substrate thereby making the absorption film generate heat and crystallizing the semiconductor layer through the heat. According to this structure, the semiconductor layer can be easily stably heated in crystallization through the heat generated from the absorption film located between the substrate and the semiconductor layer.

In the aforementioned method of fabricating a semiconductor device further comprising the step of forming the absorption film, the step of forming the absorption film may include a step of forming the absorption film on the semiconductor layer, and the step of crystallizing the semiconductor layer may include a step of directly irradiating the absorption film with the laser beam thereby making the absorption film generate heat and crystallizing the semiconductor layer through the heat. According to this structure, the semiconductor layer can be easily stably heated in crystallization through the heat generated from the absorption film located on the semiconductor layer.

In the aforementioned method of fabricating a semiconductor device including the step of crystallizing the semiconductor layer by scanning the same with the laser beam, the laser beam preferably includes a continuous-wave laser beam. According to this structure, the continuous-wave laser beam can continuously heat the semiconductor layer in the laser beam scanning direction, whereby the crystal orientation of the semiconductor layer can be inhibited from dispersion. Thus, the extensional direction of the twin plane can be further inhibited from dispersion.

The aforementioned method of fabricating a semiconductor device according to the second aspect preferably further comprises a step of forming an insulating film having a contact angle of not more than about 45° with a fused semiconductor layer on the substrate, and the step of forming the semiconductor layer preferably includes a step of forming the semiconductor layer on the insulating film to be in contact with the insulating film. According to this structure, the fused semiconductor layer can be inhibited from aggregation and bulking in crystallization, whereby a crystallization condition for increasing the time for fusing the semiconductor layer in crystallization can be employed. Consequently, the semiconductor layer can be more stably crystallized in crystal growth through unidirectional fusion and solidification for suppressing dispersion of the crystal orientation, whereby the crystal orientation can be further inhibited from dispersion. Consequently, the extensional direction of the twin plane formed on the semiconductor layer can be further inhibited from dispersion.

In the aforementioned method of fabricating a semiconductor device according to the second aspect, the semiconductor layer preferably includes a silicon film, and the step of crystallizing the semiconductor layer preferably includes a step of crystallizing an amorphous silicon film into a polycrystalline silicon film. According to this structure, the characteristics of the plurality of semiconductor elements can be easily improved and uniformized in formation of a semiconductor device comprising a plurality of semiconductor elements each including a polycrystalline silicon film having a channel region.

In the aforementioned method of fabricating a semiconductor device according to the second aspect, the semiconductor layer preferably includes a semiconductor layer serving as an active layer of a thin-film transistor. According to this structure, no carriers flowing through the channel region traverse the twin plane in the active layer of the thin-film transistor constituted of the semiconductor layer having the twin plane, whereby carrier mobility can be inhibited from reduction. Thus, the characteristics of the thin-film transistor including the active layer having the twin plane can be improved.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing the structure of a semiconductor device including a plurality of thin-film transistors according to a first embodiment of the present invention;

FIG. 2 is a model diagram showing an exemplary polycrystalline silicon film constituting an active layer of each thin-film transistor shown in FIG. 1;

FIG. 3 is a schematic diagram showing the overall structure of a laser irradiator employed for fabricating the semiconductor device according to the first embodiment of the present invention;

FIG. 4 is a perspective view showing the shape of a laser for irradiating a substrate with a laser beam in the laser irradiator shown in FIG. 3;

FIGS. 5 to 10 are sectional views for illustrating a process of fabricating the semiconductor device according to the first embodiment of the present invention;

FIG. 11 illustrates antipole figures showing crystal orientations of polycrystalline silicon films formed under different laser irradiation conditions respectively;

FIG. 12 is a sectional view showing the structure of a semiconductor device including a plurality of thin-film transistors according to a second embodiment of the present invention;

FIGS. 13 to 17 are sectional views for illustrating a process of fabricating the semiconductor device according to the second embodiment of the present invention;

FIG. 18 illustrates other antipole figures showing crystal orientations of polycrystalline silicon films formed under different laser irradiation conditions respectively;

FIGS. 19 and 20 are sectional views for illustrating a process of fabricating a semiconductor device having upper and lower wiring layers according to a third embodiment of the present invention;

FIG. 21 is a sectional view showing a sample prepared for investigating the relation between the crystal grain size and the sheet resistance of an Mo film;

FIG. 22 is a graph showing the relation between laser irradiation conditions and crystal grain sizes; and

FIG. 23 is a graph showing the relation between laser irradiation conditions and sheet resistance values.

### DESCRIPTION OF THE PREFERRED EMBODIMENTS

Embodiments of the present invention are now described with reference to the drawings.

### First Embodiment

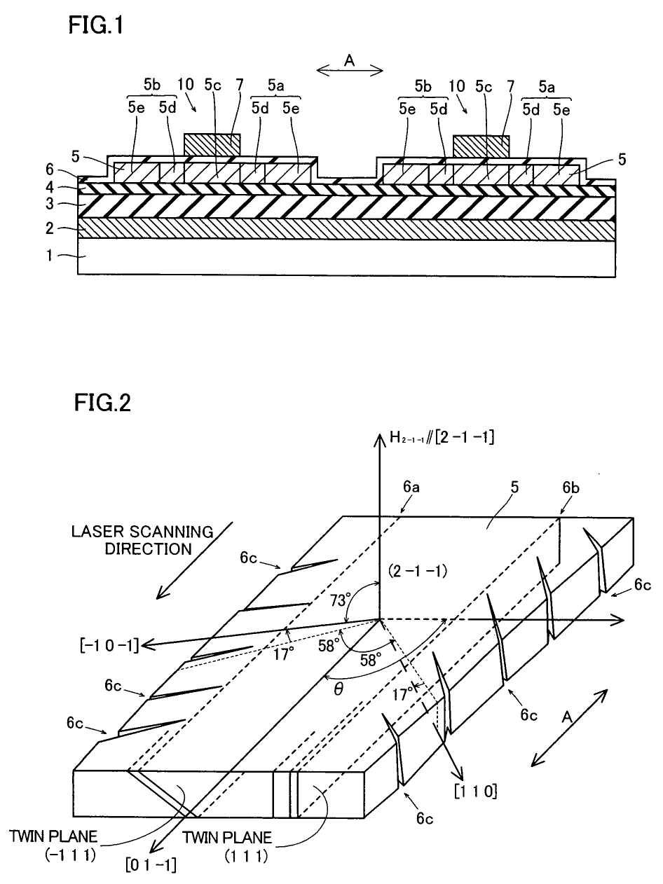

The structure of a semiconductor device including thin-film transistors according to a first embodiment of the present invention is described with reference to FIGS. 1 and 2. FIG. 2 shows an exemplary one of orientation groups capable of attaining effects of the present invention.

In the semiconductor device including thin-film transistors according to the first embodiment, an Mo film 2 of about 50 nm in thickness having a higher melting point than silicon is formed on a quarts substrate 1, as shown in FIG. 1. The quartz substrate 1 is an example of the “substrate” in the present invention, and the Mo film 2 is an example of the “absorption film” in the present invention. An insulating film 3 of SiO₂ having a thickness of about 80 nm is formed on the Mo film 2. Another insulating film 4 of SiNₓ having a thickness of about 20 nm with a contact angle of not more than about 45° with fused silicon layer is formed on the insulating film 3. A plurality of polycrystalline silicon films 5 constituting active layers of n-type thin-film transistors 10 are formed on prescribed regions of the insulating film 4 in the form of islands at prescribed intervals. FIG. 1 shows only two polycrystalline silicon film 5, in order to simplify the illustration. Each polycrystalline silicon film 5 has a thickness of about 50 nm, with a face-centered cubic lattice crystal structure. The (2 −1 −1) plane of each polycrystalline silicon film 5 is parallel to the main surface of the quartz substrate 1, for example. The polycrystalline silicon film 5 is an example of the “semiconductor layer” or the “active layer” in the present invention.

According to the first embodiment, each polycrystalline silicon film 5 has a plurality of twin planes 6a and 6b extending in the crystal orientation [0 1 −1] as shown in FIG. 2, for example. The twin planes 6a and 6b are the (−1 1 1) and (1 1 1) planes respectively. A plurality of subboundaries 6c resulting from slight deviation of the orientations of crystal grains are formed on regions outward beyond the twin planes 6a and 6b of the polycrystalline silicon film 5.

As shown in FIG. 1, a source region 5a and a drain region 5b are formed on each polycrystalline silicon film 5, to hold a channel region 5c therebetween. Each of the source and drain regions 5a and 5b has an LDD (lightly doped drain) structure consisting of an n-type low-concentration impurity region 5d and an n-type high-concentration impurity region 5e.

According to the first embodiment, the channel region 5c is so formed that carriers flowing through the channel region 5c in a channel length direction hardly traverse the twin planes 6a and 6b shown in FIG. 2, for example. More specifically, the channel region 5c is so formed that the carriers flowing through the channel region 5c in the channel length direction flow in the same direction as the extensional direction (crystal orientation [0 1 −1]) of the twin planes 6a and 6b when a thin-film transistor is formed by each polycrystalline silicon film 5 shown in FIG. 2. In other words, the angle formed by the extensional direction of the twin planes 6a and 6b formed on the polycrystalline silicon film 5 and the direction (direction A: channel length direction) in which the carriers flow through the channel region 5c of the polycrystalline silicon film 5 is 0°. The crystal orientation [0 1 −1] corresponding to the direction (direction A in FIGS. 1 and 2: channel length direction) in which the carriers flow through the channel region 5c can be expressed in a form orientation <1 1 0>. Assuming that <u v w> represents the crystal form orientation (=<1 1 0>) corresponding to the direction (direction A: channel length direction) in which the carriers flow through the channel region 5c, the following formula is obtained:
u−v−w=1−1−0=0
In other words, the angle θ formed by the crystal orientation corresponding to the direction (direction A: channel length direction) in which the carriers flow through the channel region 5c and the vector of the plane normals of the twin planes 6a and 6b is 90° according to the first embodiment. This satisfies the following relational expression showing the condition for setting the angle α (=90°−θ) formed by the crystal orientation corresponding to the direction (direction A: channel length direction) in which the carriers flow through the channel region 5c and the twin planes 6a and 6b to about 00 to about 10°:
|u−v−w|/(u²+v²+w²)^{1/2}≦0.3 (where u≧v≧w≧0)
This relational expression is now described.

In general, twin planes remarkably influence crystal growth of a semiconductor having a face-centered cubic structure. According to the so-called solid phase epitaxy for crystallizing an amorphous silicon film having no impurities in a solid-phase state by heating the same to about 600° C. in an electric furnace, for example, twin planes so prompt crystal growth that crystals grow mainly in the extensional directions of the twin planes. According to the solid phase epitaxy, however, a plurality of twin planes nonparallel to each other are formed, to result in inconsistent crystal growth directions (extensional directions of the twin planes). According to MIC (metal induced crystallization) for lowering the crystallization temperature with a catalyst of Ni or the like, on the other hand, crystals grow along the <1 1 1> orientation while twin planes are formed in a direction perpendicular to the crystal growth direction. Thus, the twin planes are remarkably influential in crystal growth, and the growth orientation (crystal orientation) generally depends on the relation to formation of the twin planes. However, this does not apply to a case of controlling the crystal growth direction with a seed crystal or a case of controlling the orientation of nucleation for crystal growth with influence by a substrate since the crystal orientation depends on interaction with the seed crystal or the substrate in this case.

According to the first embodiment, each polycrystalline silicon film 5 is formed without controlling the crystal growth direction with a seed crystal or a substrate. In the polycrystalline silicon film 5 according to the first embodiment, formation of the twin planes 6a and 6b and the crystal orientation are closely related to each other.

A twin plane of a face-centered cubic structure, expressed as {1 1 1 1} in form indication, has four nonparallel orientations (1 1 1), (1 1 −1), (1 −1 1) and (−1 1 1). These planes constitute a regular tetrahedron. These planes are parallel or perpendicular to a specific orientation (crystal growth orientation, for example). When the channel region 5c is so formed that carriers flow substantially in parallel with the specific orientation along the form orientation <u v w> (where u≧v≧w≧0), the angle α(=90°−θ) formed by the specific orientation and a twin plane most parallel thereto can be obtained according to the following formula:
cos(90°−α)=|u−v−w|/(u²+v²+w²)^{1/2}×3^{1/2})
The condition for |α|≦10° is as follows:
|u−v−w|/(u²+v²+w²)^{1/2}≦0.3
The angle α is equal to 0° along the crystal orientation [0 1 −1], for example.

Twin planes cannot intersect with each other, and hence there is no twin plane intersecting with a twin plane present in a crystal grain. Referring to FIG. 2, the twin planes 6a and 6b, which are unparallel to each other, can be present since the same do not intersect with each other in the crystal. While the (1 1 −1) and (1 −1 1) planes can also form twin planes, no such twin planes formed by the (1 1 −1) and (1 −1 1) planes can be present since the same intersect with the twin planes 6a and 6b. In other words, the twin planes 6a and 6b are formed in parallel with the direction in which the carriers flow through the channel region 5c, so as to suppress formation of other twin planes across the direction in which the carriers flow through the channel region 5c.

As shown in FIG. 1, a gate insulating film 6 of SiO₂ or SiNₓ having a thickness of about 100 nm is formed to cover the polycrystalline silicon film 5. A gate electrode 7 of Mo, which is high-melting point metal, having a thickness of about 50 nm is formed on a portion of the gate insulating film 6 located on each channel region 5c. Each gate electrode 7, the gate insulating film 6, each pair of source regions 5a and each pair of drain regions 5b constitute each n-type thin-film transistor 10. The plurality of n-type thin-film transistors 10 provided on the quartz substrate 1 constitute an n-type thin-film transistor group. The n-type thin-film transistors 10 are examples of the “semiconductor element” or the “thin-film transistor” in the present invention.

According to the first embodiment, as hereinabove described, the polycrystalline silicon film 5 constituting each of the plurality of n-type thin-film transistors 10 is formed to have the twin planes 6a and 6b extending along the crystal orientation [0 1 −1], for example, so that carriers flows through the channel region 5c in the direction (direction A) corresponding to the crystal orientation [0 1 −1], whereby the carriers flowing through the channel region 5c can be inhibited from traversing the twin planes 6a and 6b while inhibiting formation of twin planes traversing the direction in which the carriers flow, so that carrier mobility can be inhibited from reduction. Thus, the characteristics of the plurality of n-type thin-film transistors 10 each including the polycrystalline silicon film 5 formed with the twin planes 6a and 6b can be improved. Also when the polycrystalline silicon film 5 formed with the twin planes 6a and 6b and another polycrystalline silicon film 5 formed with no twin planes 6a and 6b are present on the same quartz substrate 1, the carriers flowing through the channel region 5c of the polycrystalline silicon film 5 formed with the twin planes 6a and 6b can be so inhibited from traversing the twin planes 6a and 6b that the n-type thin-film transistors 10 including the polycrystalline silicon film 5 formed with the twin planes 6a and 6b and the other polycrystalline silicon film 5 formed with no twin planes 6a and 6b can be inhibited from differing in carrier mobility from each other. Consequently, the characteristics of the plurality of n-type thin-film transistors 10 can be inhibited from dispersion, so that the characteristics can be uniformized.

According to the first embodiment, further, the crystal orientation <u v w> corresponding to the direction in which the carriers flow through the channel region 5c is set to satisfy the following formula:
|u−v−w|/(u²+v²+w²)^{1/2}≦0.3 (where u≧v≧w≧
0 and the angle formed by the direction perpendicular to the main surface of the quartz substrate 1 and the crystal orientation <1 1 1> exceeds 10°)

Thus, the angle formed by the extensional direction of the twin planes 6a and 6b formed on the polycrystalline silicon film 5 and the direction (direction A) in which the carriers flow through the channel region 5c of the polycrystalline silicon film 5 can be set in the range of about 0° to about 10° (0° according to the first embodiment), whereby the carriers flowing through the channel region 5c can be easily inhibited from traversing the twin planes 6a and 6b while suppressing formation of twin planes across the direction in which the carriers flow.

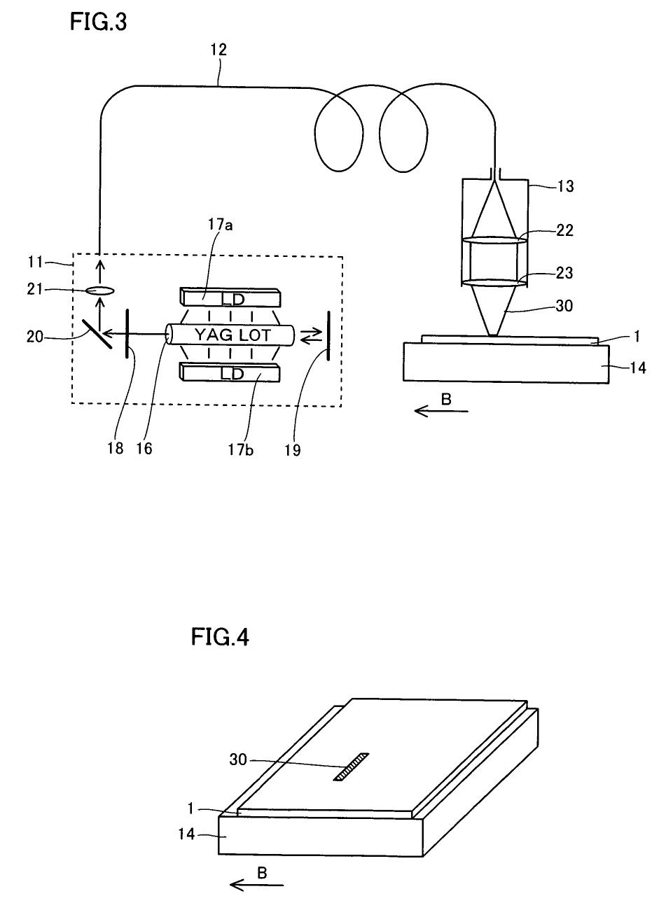

The structure of a laser irradiator employed for fabricating the semiconductor device according to the first embodiment is now described with reference to FIGS. 3 and 4.

The laser irradiator employed for fabricating the semiconductor device according to the first embodiment comprises a laser oscillator 11, an optical fiber member 12, an irradiation optical system 13 and a heater plate 14, as shown in FIG. 1. The laser oscillator 11 and the irradiation optical system 13 are connected with each other through the optical fiber member 12. The heater plate 14 is set to be relatively movable in the short-side direction of a laser beam 30, as shown in FIG. 4. The quartz substrate 1 formed with an amorphous silicon film to be crystallized is set on the heater plate 14 to be relatively movable.

As shown in FIG. 3, semiconductor lasers (LD) 17a and 17b for excitation are provided in the laser oscillator 11 to hold a YAG lot 16, a crystal for oscillating a YAG laser, therebetween. Mirrors 18 and 19 for oscillating a laser beam emitted from the YAG lot 16 are provided on both longitudinal sides of the YAG lot 16. A reflecting mirror 20 is arranged on an extension of the optical fiber member 12 connected to the laser oscillator 11, in order to convert the traveling direction of the laser beam passing through the mirror 18 toward the optical fiber member 12. Further, a lens 21 is arranged between the reflecting mirror 20 provided on the extension of the optical fiber 12 connected to the laser oscillator 11 and the optical fiber member 12, in order to condense the laser beam. Lenses 22 and 23 for condensing the laser beam from the optical fiber member 12 are provided in the irradiation optical system 13.

A process of fabricating the semiconductor device according to the first embodiment is now described with reference to FIGS. 1 to 10.

As shown in FIG. 5, the Mo film 2 of about 50 nm in thickness for serving as an absorption film having a higher melting point than silicon is formed on the quartz substrate 1 by sputtering. Then, the insulating film 3 of SiO₂ having the thickness of about 80 nm is formed on the Mo film 2 by plasma CVD.

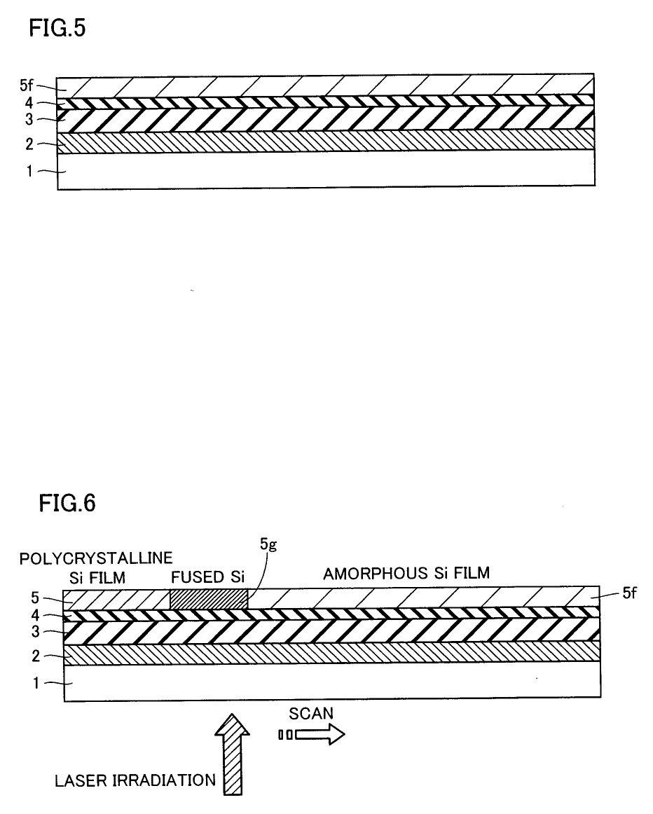

Then, the other insulating film 4 of SiNₓ having the thickness of about 20 nm is formed on the insulating film 3 by plasma CVD under film forming conditions for setting the contact angle with fused silicon layer 5g (see FIG. 6) to not more than about 45°. In this case, the insulating film 4 is formed under a substrate temperature of about 400° C. to about 450° C. (about 400° C., for example), a pressure of about 700 Pa and power density of about 2 W/cm² with SiH₄ gas, NH₃ gas and N₂ gas in flow ratios of 2:1 to 2 (1.5, for example):100. According to these conditions for forming the insulating film 4, wettability between the fused silicon 5g and the insulating film 4 can be improved through the insulating film 4 having the small contact angle with the fused silicon 5g. Thereafter an amorphous silicon film 5f having a thickness of about 50 nm is formed on the insulating film 4. The amorphous silicon film 5f is an example of the “semiconductor layer” in the present invention.

Then, the quartz substrate 1 including the amorphous silicon film 5f shown in FIG. 5 is preheated under a temperature condition of about 170° C. Thereafter the quartz substrate 1 having the structure shown in FIG. 5 is fixed onto the heater plate 14 shown in FIG. 3 to direct the back surface thereof upward. The heater plate 14 receiving the quartz substrate 1 is moved along arrow B in FIG. 3 (short-side direction of the YAG laser) at a rate (scanning rate) of about 1000 mm/s for irradiating the back surface (see FIG. 6) of the quartz substrate 1 with the laser beam 30 of a continuous-wave YAG laser condensed in the form of a rectangle of about 4 mm by about 0.1 mm from the irradiation optical system 13.

Thus, a portion of the Mo film 2 located on the region irradiated with the YAG laser beam 30 generates heat to convert the amorphous silicon film 5f to the fused silicon layer 5g with this heat, as shown in FIG. 6. The fused silicon layer 5g is an example of the “fused semiconductor layer” in the present invention. This fused silicon layer 5g is crystallized to form the polycrystalline silicon films 5. According to the first embodiment, the wettability between the fused silicon 5g and the insulating film 4 is improved as hereinabove described thereby inhibiting the fused silicon 5g from aggregation and bulking, whereby the time for fusing silicon can be increased in crystallization, i.e., a condition closer to equilibrium can be selected. Consequently, dispersion of the crystal orientations can be suppressed in crystallization, whereby the extensional direction of the twin planes 6a and 6b (see FIG. 2) formed on the polycrystalline silicon films 5 can be inhibited from dispersion.

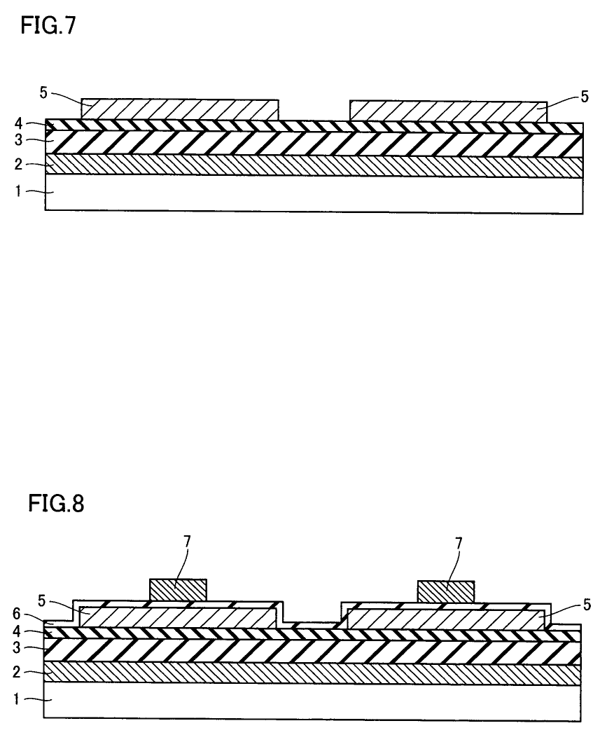

As shown in FIG. 7, the polycrystalline silicon films 5 are islanded by patterning by photolithography and etching. Thus, the plurality of islanded polycrystalline silicon films 5 are formed for serving as the active layers of the n-type thin-film transistors 10 (see FIG. 1).

As shown in FIG. 8, the gate insulating film 6 of SiO₂ or SiNₓ having the thickness of about 100 nm is formed by plasma CVD to cover the overall surface. Thereafter another Mo film (not shown) having a thickness of about 50 nm is formed by sputtering to cover the overall surface, and thereafter patterned for forming the gate electrodes 7 constituting the n-type thin-film transistors 10 (see FIG. 1) on the polycrystalline silicon films 5.

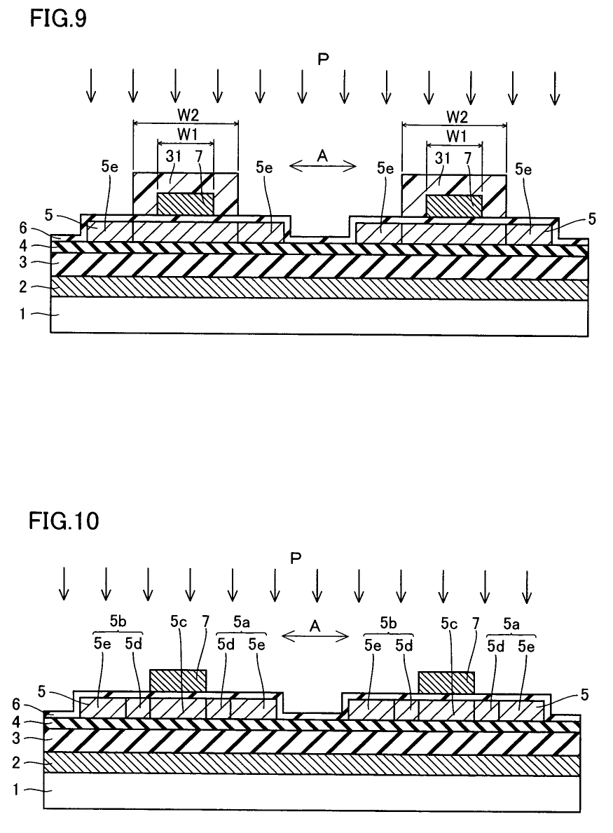

As shown in FIG. 9, resist films 31 are formed to cover the gate electrodes 7. At this time, the resist films 31 are so formed as to have a width W2 larger than the width W1 of the gate electrodes 7 in the direction A. Thereafter P (phosphorus) is ion-implanted into the polycrystalline silicon films 5 through the resist films 31 serving as masks under ion implantation conditions of implantation energy of about 80 keV and a dose of about 7×10¹⁴ cm⁻². Thus, the n-type high-concentration impurity regions 5e are formed on the polycrystalline silicon films 5. Thereafter the resist films 31 are removed.

As shown in FIG. 10, P (phosphorus) is ion-implanted into the polycrystalline silicon films 5 again through the gate electrodes 7 serving as masks under ion implantation conditions of implantation energy of about 80 keV and a dose of about 3×10¹³ cm⁻². Thus, the n-type low-concentration impurity regions 5d are formed on the polycrystalline silicon films 5. Consequently, the source and drain regions 5a and 5b having the LDD structure and the channel regions 5c located between the source and drain regions 5a and 5b are formed on the polycrystalline silicon films 5.

According to the first embodiment, the channel regions 5c are so formed that carriers flow through the channel regions 5c along the scanning direction (crystal orientation [0 1 −1] in the example shown in FIG. 2) of the YAG laser.

Thereafter rapid heat treatment is performed by RTA (rapid thermal annealing), for activating the impurity implanted into the polycrystalline silicon films 5. Thus, the n-type thin-film transistors 10 constituted of the gate electrodes 7, the gate insulating film 6 and the source and drain regions 5a and 5b are formed as shown in FIG. 1.

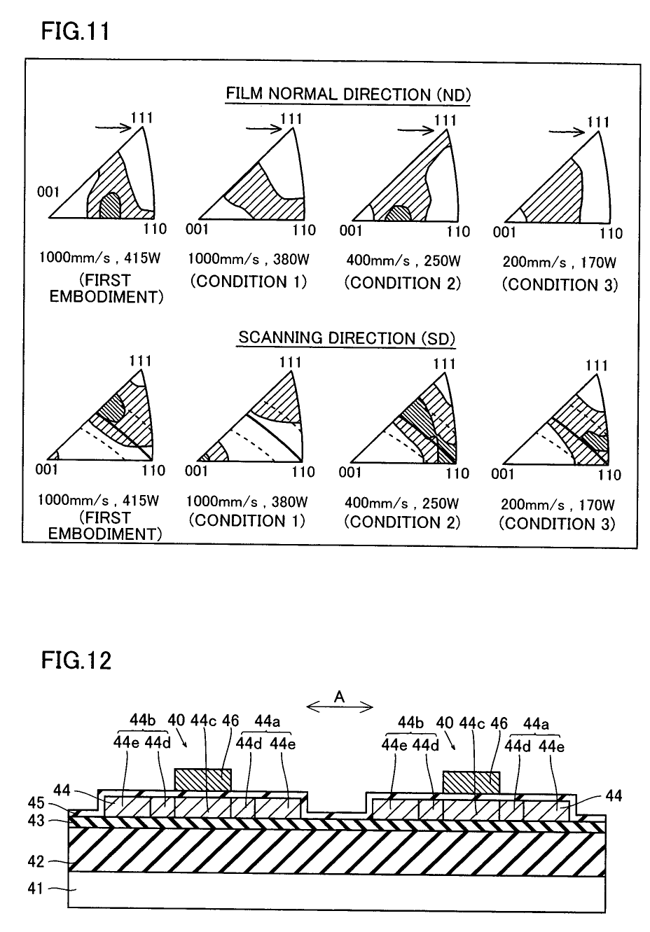

Results obtained by measuring the crystal orientation of a polycrystalline silicon film actually crystallized under the YAG laser irradiation conditions according to the first embodiment are now described with reference to FIG. 11. The crystal orientations of other polycrystalline silicon films crystallized under YAG laser irradiation conditions (scanning rate and power) 1 to 3 were also measured in addition to the polycrystalline silicon film actually crystallized under the YAG laser irradiation conditions according to the first embodiment. The conditions 1 to 3 are scanning rates of about 1000 mm/s, about 400 mm/s and about 200 mm/s respectively and power levels of about 380 W, about 250 W and about 170 W respectively. The crystal orientations of the polycrystalline silicon films were measured through EBSPs (electron back scattering patterns).

An antipole figure illustrates which plane of each crystal of a substance consisting of a large number of crystals (grains) is directed to a prescribed direction fixed in the substance or a space outside the substance as contour lines on a plane of stereographic projection with Miller's indices. When the crystal is cubic, the antipole figure is generally shown in a basic triangle (011-011-111) of the plane of stereographic projection. The antipole figure is disclosed in “X-Sen Kaisetsu Yoron” by B. D. Cullity, translated into Japanese by Gentaro Matsumura, Agne, Jun. 20, 1982, pp. 290 to 292, for example. In each antipole figure shown in the lower half of FIG. 11, a laser scanning direction (SD) is the prescribed direction fixed in the substance or the space outside the substance, corresponding to a YAG laser scanning direction. In each antipole figure shown in the upper half of FIG. 11, on the other hand, a film normal direction (ND) is the prescribed direction fixed in the substance or the space outside the substance, corresponding to the normal direction of a plane of the polycrystalline silicon film parallel to the main surface of a substrate. In each antipole figure shown in the lower half of FIG. 11, a portion held between broken lines in the basic triangle of the plane of stereographic projection is a region satisfying the following condition for setting the angle α formed by the crystal orientation <u v w> and twin planes to about 0° to about 10°:
|u−v−w|/(u²+v²+w²)^{1/2}≦0.3
Further, a region located above a thick line in the basic triangle of the plane of stereographic projection is that satisfying the following condition for setting the angle α formed by the crystal orientation <u v w> and the twin planes to about 0°:
u−v−w=0 (where u≧v≧w≧0)
In the basic triangle of the plane of stereographic projection shown in FIG. 11, further, a region hatched at smaller intervals can be classified as that having a large number of crystals having the orientation in the basic triangle, and a region hatched at larger intervals can be classified as that having a smaller number of crystals having the orientation than the region hatched at smaller intervals. In addition, an unhatched region in the basic triangle of the plane of stereographic projection shown in FIG. 11 is that hardly having crystals of the orientation. The abundance of crystals is expressed in an area ratio.

Referring to the antipole figures (lower half of FIG. 11) with reference to the YAG laser scanning direction (SD), it has been proved that a peak (region hatched at smaller intervals) is present in the vicinity of the thick line under the YAG laser irradiation conditions (about 1000 mm/s and about 415 W) according to the first embodiment. Referring to the antipole figures (upper half of FIG. 11) with reference to the normal direction (ND) of the polycrystalline silicon films parallel to the main surfaces of the substrates, it has been proved that no peak (region hatched at smaller intervals) is present in the vicinity of the crystal orientation <1 1 1> under the YAG laser irradiation conditions (about 1000 mm/s and about 415 W) according to the first embodiment. When a peak is present in the vicinity of the crystal orientation <1 1 1> in an antipole figure with reference to the normal direction (ND) of a polycrystalline silicon film parallel to the main surface of a substrate, a peak is present in the vicinity of a thick line in an antipole figure with reference to a YAG laser scanning direction (SD) regardless of the crystal orientation in a film plane. In other words, a result of an antipole figure with reference to a YAG laser scanning direction (SD) does not express relation to a twin plane if a peak is present in the vicinity of a crystal orientation <1 1 1> (region in which the angle formed by a direction perpendicular to the main surface of a substrate and the crystal orientation <1 1 1> exceeds 10°) in an antipole figure with reference to a normal direction (ND) of a plane of a polycrystalline silicon film parallel to the main surface of the substrate. Under the YAG laser irradiation conditions (about 1000 mm/s and about 415 W) according to the first embodiment, no peak is present in the vicinity of the crystal orientation <1 1 1>, and hence the result of the antipole figure with reference to the YAG laser scanning direction (SD) can be regarded as expressing relation to a twin plane. Therefore, it can be said that a polycrystalline silicon film prepared under the YAG laser irradiation conditions according to the first embodiment has a large number of crystals having such orientational relation that the angle formed by twin planes and the laser scanning direction (SD) is within about 10°.

According to the first embodiment, each channel region 5c is so formed that the carriers flowing through the channel region 5c flow in the YAG laser scanning direction (parallel to the crystal orientation of the polycrystalline silicon film 5), whereby deviation between the extensional direction of the twin planes 6a and 6b (see FIG. 2) formed on the polycrystalline silicon film 5 and the direction in which the carriers flow through the channel region 5c can be set within the range of about 100.

Referring to the antipole figures (lower half in FIG. 11) with reference to the YAG laser scanning direction (SD), it has been proved that no peak (region hatched at smaller intervals) is present in the vicinity of the thick line under the conditions 1 (about 1000 mm/s and about 380 W) of the same scanning rate as that in the YAG laser irradiation conditions according to the first embodiment and weakened power. This is conceivably because the polycrystalline silicon film was crystallized under a more non-equilibrium condition since the time for fusing silicon was reduced and a cooling rate was increased due to the weakened power of the YAG laser.

It has also been proved that peaks (regions hatched at smaller intervals) are present in the vicinity of the thick lines under the conditions 2 (about 400 mm/s and about 250 W) and the conditions 3 (about 200 mm/s and about 170 W) of slower scanning rates than that in the YAG laser irradiation conditions according to the first embodiment and power levels weakened in response thereto, similarly to the first embodiment.

Referring to the antipole figures (upper half in FIG. 11) with reference to the normal direction (ND) of the planes of the polycrystalline silicon films perpendicular to the substrates, no peaks were present in the vicinity of the crystal orientations <1 1 1> (regions in which the angles formed by the directions perpendicular to the main surfaces of the substrates and the crystal orientations <1 1 1> exceed 100) under the conditions 2 and 3, similarly to the YAG laser irradiation conditions according to the first embodiment. In other words, no peaks are present in the vicinity of the crystal orientations <1 1 1> under the conditions 2 and 3 similarly to the YAG laser irradiation conditions according to the first embodiment, whereby the results of the antipole figures with reference to the YAG laser scanning directions (SD) can be regarded as expressing relation to twin planes.

Thus, it has been proved that the number of crystals is increased in the region (held between the broken lines) satisfying the following formula expressing the condition for setting the angle α formed by the crystal orientation in the laser scanning direction (SD) and the twin planes to about 00 to about 100 similarly to the first embodiment when the YAG laser irradiation conditions 2 or 3 are employed:
|u−v−w|/√ (u²+v²+w²)^{1/2}≦0.3
Therefore, it was possible to form a polycrystalline silicon film having such a crystal orientation that no carriers flowing in a channel length direction traverse twin planes under the YAG laser irradiation conditions 2 or 3, similarly to the crystal orientation of the polycrystalline silicon film 5 according to the first embodiment. This is conceivably because the polycrystalline silicon film was crystallized under a condition closer to equilibrium since a time for fusing silicon was increased and a cooling rate was reduced due to the slow scanning rate of the YAG laser beam.

In the fabrication process according to the first embodiment, as hereinabove described, the quartz substrate 1 is irradiated with the YAG laser beam and scanned with the YAG laser beam when each polycrystalline silicon film 5 is formed by heating the amorphous silicon film 5f, whereby the amorphous silicon film 5f can be supplied with a large temperature gradient in crystallization, dissimilarly to a case of entirely heating the amorphous silicon film 5f through an electric furnace or the like. Further, the crystal orientation of the polycrystalline silicon film 5 can be easily regulated by performing crystal growth from a low-temperature region toward a high-temperature region in a temperature gradient. When the amorphous silicon film 5f is so crystallized that the laser scanning direction and the twin planes 6a and 6b of the polycrystalline silicon film 5 are approximately parallel to each other while carriers flow in parallel with the laser scanning direction, the carriers flowing through the channel regions 5c can be easily inhibited from traversing the twin planes 6a and 6b.

According to the first embodiment, the amorphous silicon film 5f can be stably heated continuously in the YAG laser beam scanning direction due to the continuous-wave YAG laser beam having a stable output, whereby the crystal orientation of the polycrystalline silicon film 5 can be inhibited from dispersion. Thus, the extensional direction of the twin planes 6a and 6b can be further inhibited from dispersion.

According to the first embodiment, further, the YAG laser beam is rectangularly condensed while the quartz substrate 1 is scanned in the short-side direction of the YAG laser beam so that the temperature gradient in the YAG laser beam scanning direction can be steepened, whereby the orientations of crystals growing from the low-temperature region toward the high-temperature region can be effectively inhibited from dispersion. Thus, the twin planes 6a and 6b can be further effectively inhibited from dispersion.

According to the first embodiment, in addition, the Mo film (absorption film) 2 is made to generate heat for forming the polycrystalline silicon film 5 through this heat so that a stable laser not absorbed by a semiconductor but absorbed by the Mo film 2 can be employed, whereby the amorphous silicon film 5f can be stably heated in crystallization. Thus, the polycrystalline silicon film 5 formed with the twin planes 6a and 6b inhibited from dispersion in extensional direction can be formed with high productivity.

As a result of analyzing the antipole figures shown in FIG. 11, most frequently observed crystal orientations in the laser scanning direction (SD) and the direction (ND) perpendicular to the main surfaces of the substrates were [2 1 1] and [1 −2 0] respectively. Further, only single twin planes (−1 1 1) extending in the laser scanning direction (SD) were observed. While this result of analysis is different from the crystal orientation of the polycrystalline silicon film shown in FIG. 2, each of the polycrystalline silicon films most frequently exhibiting the aforementioned crystal orientations ([2 1 1] in SD and [1 −2 0] in ND) and the polycrystalline silicon film shown in FIG. 2 have the same effects of forming twin planes extending in the laser scanning direction (SD). Thus, it is possible to attain such an effect that a channel region in which no carriers traverse twin planes can be formed when a channel region is formed in parallel with the laser scanning direction (SD) in either case.

### Second Embodiment

FIG. 12 shows a semiconductor device according to a second embodiment of the present invention. Referring to FIG. 12, polycrystalline silicon films constituting active layers of thin-film transistors are formed by irradiating an amorphous film with a laser beam from a side opposite to a substrate according to the second embodiment, dissimilarly to the aforementioned first embodiment.

In the semiconductor device including thin-film transistors according to the second embodiment, an insulating film 42 of SiO₂ having a thickness of about 600 nm is formed on a quartz substrate 41, as shown in FIG. 12. The quartz substrate 41 is an example of the “substrate” in the present invention. Another insulating film 43 of SiNₓ of about 20 nm in thickness having a contact angle of not more than about 45° with fused silicon is formed on the insulating film 42. A plurality of polycrystalline silicon films 44 constituting active layers of n-type thin-film transistors 40 are formed on prescribed regions of the insulating film 43 in the form of islands at prescribed intervals. FIG. 12 shows only two polycrystalline silicon films 44, in order to simplify the illustration. Each polycrystalline silicon film 44 has a thickness of about 50 nm, with a face-centered cubic lattice crystal structure. The polycrystalline silicon film 44 is an example of the “semiconductor layer” or the “active layer” in the present invention.

A source region 44a and a drain region 44b are formed on each polycrystalline silicon film 44, to hold a channel region 44c therebetween. Each of the source and drain regions 44a and 44b has an LDD structure consisting of an n-type low-concentration impurity region 44d and an n-type high-concentration impurity region 44e.

According to the second embodiment, the channel region 44c is so formed that carriers flowing through the channel region 44c in a channel length direction hardly traverse twin planes (not shown), similarly to the channel region 5c according to the aforementioned first embodiment. More specifically, the channel region 44c is so formed that the carriers flowing through the channel region 44c in the channel length direction flow in the same direction as the extensional direction (crystal orientation [0 1 −1], for example) of the twin planes. In other words, the angle formed by the extensional direction of the twin planes formed on the polycrystalline silicon film 44 and the direction (direction A) in which the carriers flow through the channel region 44c of the polycrystalline silicon film 44 is about 0° to about 10° in the second embodiment, similarly to the aforementioned first embodiment. In other words, the angle α formed by the crystal orientation corresponding to the direction (direction A) in which the carriers flow through the channel region 44c and the twin planes is about 0° to about 10° according to the second embodiment, similarly to the aforementioned first embodiment. In this case, the following relational expression of the condition for setting the angle α formed by the crystal orientation <u v w> corresponding to the direction (direction A) in which the carriers flow through the channel region 44c and the twin planes to about 0° to about 10° must be satisfied:
|u−v−w|(u²+v²+w²)^{1/2}≦0.3 (where u≧v≧w≧0)

A gate insulating film 45 of SiO₂ having a thickness of about 100 nm is formed to cover the polycrystalline silicon film 44. A gate electrode 46 of Mo having a thickness of about 50 nm with a higher melting point than silicon is formed on a portion of the gate insulating film 45 located on each channel region 44c. Each gate electrode 46, the gate insulating film 45, each pair of source regions 44a and each pair of drain regions 44b constitute each n-type thin-film transistor 40. The plurality of n-type thin-film transistors 40 provided on the quartz substrate 41 constitute an n-type thin-film transistor group. The n-type thin-film transistors 40 are examples of the “semiconductor element” or the “thin-film transistor” in the present invention.

According to the second embodiment, as hereinabove described, each polycrystalline silicon film 44 is so formed that the twin planes extend in the direction within about 10° from the direction (direction A) in which the carriers flow through the channel region 44c, whereby the carriers flowing through the channel region 44c can be inhibited from traversing the twin planes and hence carrier mobility can be inhibited from reduction, similarly to the aforementioned first embodiment. Thus, the characteristics of the plurality of n-type thin-film transistors 40 including the polycrystalline silicon films 44 formed with the twin planes can be improved similarly to the aforementioned first embodiment. Also when the polycrystalline silicon film 44 formed with the twin planes and another polycrystalline silicon film 44 formed with no twin planes are present on the same quartz substrate 41, the carriers flowing through the channel region 44c of the polycrystalline silicon film 44 formed with the twin planes can be so inhibited from traversing the twin planes that the n-type thin-film transistors 40 including the polycrystalline silicon film 44 formed with the twin planes and the other polycrystalline silicon film 44 formed with no twin planes can be inhibited from differing in carrier mobility from each other. Consequently, the characteristics of the plurality of n-type thin-film transistors 40 can be inhibited from dispersion so that the characteristics can be uniformized, similarly to the aforementioned first embodiment.

The remaining effects of the second embodiment are similar to those of the aforementioned first embodiment.

A process of fabricating the semiconductor device according to the second embodiment is now described with reference to FIGS. 12 to 17.

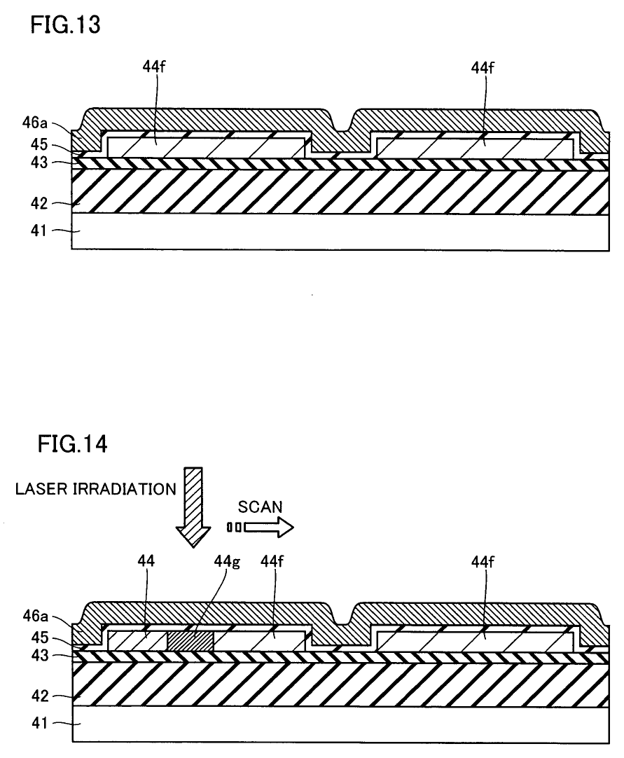

As shown in FIG. 13, the insulating film 42 of SiO₂ having the thickness of about 600 nm is formed on the quartz substrate 41 by plasma CVD. Then, the other insulating film 43 of SiNₓ having the thickness of about 20 nm is formed on the insulating film 42 by plasma CVD under film forming conditions for setting the contact angle with fused silicon 44g (see FIG. 14) to not more than about 45°. In this case, the insulating film 43 is formed under a substrate temperature of about 400° C. to about 450° C. (about 400° C., for example), a pressure of about 700 Pa and power density of about 2 W/cm² with SiH₄ gas, NH₃ gas and N₂ gas in flow ratios of 2:1 to 2 (1.5, for example):100. Thereafter an amorphous silicon film 44f having a thickness of about 50 nm is formed on the insulating film 43, and thereafter islanded by patterning. The amorphous silicon film 44f is an example of the “semiconductor layer” in the present invention.

Then, the gate insulating film 45 of SiO₂ having the thickness of about 100 nm is formed by plasma CVD to cover the overall surface. Thereafter an Mo film 46a having a thickness of about 50 nm is formed by sputtering to cover the overall surface. The Mo film 46a is an example of the “absorption film” in the present invention.

As shown in FIG. 14, the quartz substrate 41 including the amorphous silicon film 44f shown in FIG. 13 is preheated under a temperature condition of about 200° C. Thereafter the Mo film 46a is irradiated with a continuous-wave YAG laser beam condensed in the form of a rectangle of about 0.1 mm by about 4 mm and scanned at a scanning rate of about 800 mm/s in the short-side direction of the YAG laser (crystal orientation [0 1 −1]). Thus, a portion of the Mo film 46a located on the region irradiated with the YAG laser beam generates heat to convert the amorphous silicon film 44f to the fused silicon 44g with this heat. The fused silicon 44g is an example of the “fused semiconductor” in the present invention. The fused silicon 44g is crystallized to form the polycrystalline silicon films 44 serving as active layers of the n-type thin-film transistors 40.

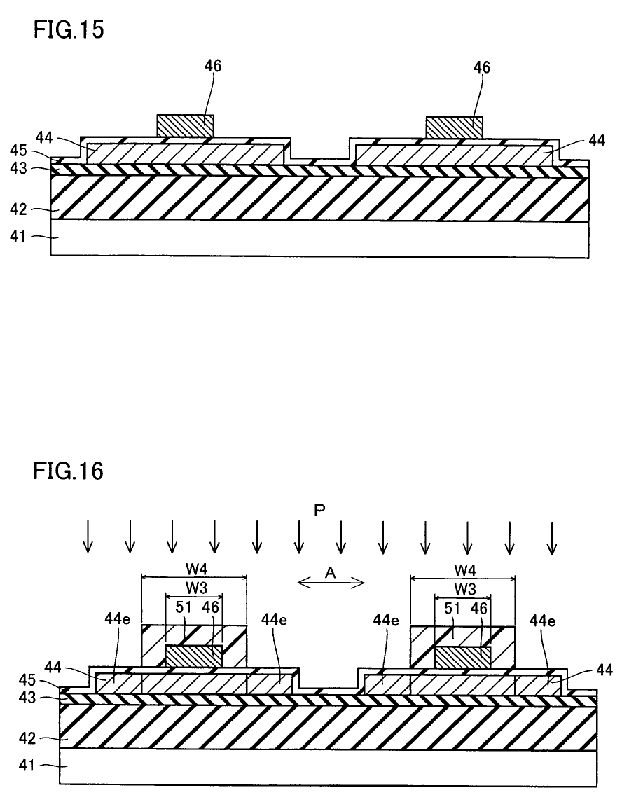

As shown in FIG. 15, the Mo film 46a (see FIG. 14) is patterned for forming the gate electrodes 46 constituting the n-type thin-film transistors 40 (see FIG. 12) on the polycrystalline silicon films 44.

As shown in FIG. 16, resist films 51 are formed to cover the gate electrodes 46. At this time, the resist films 51 are so formed as to have a width W4 larger than the width W3 of the gate electrodes 46 in the direction A. Thereafter P (phosphorus) is ion-implanted into the polycrystalline silicon films 44 through the resist films 51 serving as masks under ion implantation conditions of implantation energy of about 80 keV and a dose of about 7×10¹⁴ cm⁻². Thus, the n-type high-concentration impurity regions 44e are formed on the polycrystalline silicon films 44. Thereafter the resist films 51 are removed.

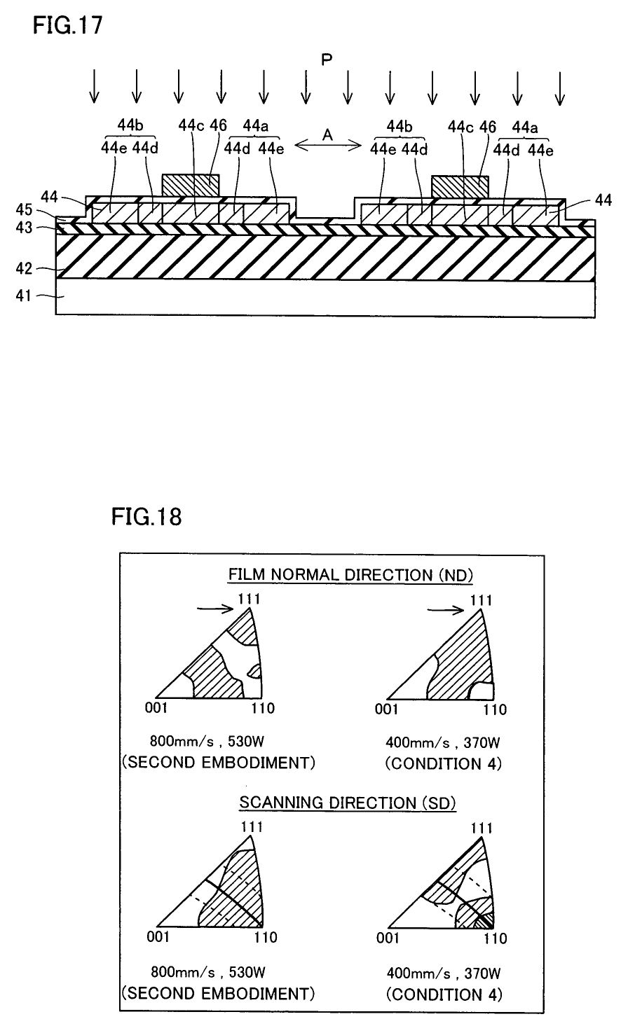

As shown in FIG. 17, P (phosphorus) is ion-implanted into the polycrystalline silicon films 44 again through the gate electrodes 46 serving as masks under ion implantation conditions of implantation energy of about 80 keV and a dose of about 3×10¹³ cm⁻². Thus, the n-type low-concentration impurity regions 44d are formed on the polycrystalline silicon films 44. Consequently, the source and drain regions 44a and 44b having the LDD structure and the channel regions 44c located between the source and drain regions 44a and 44b are formed on the polycrystalline silicon films 44.

According to the second embodiment, the amorphous silicon film 44f is previously formed by patterning so that carriers flow through the channel regions 44c along the YAG laser scanning direction.

Thereafter rapid heat treatment is performed by RTA, for activating the impurity implanted into the polycrystalline silicon films 44. Thus, the n-type thin-film transistors 40 constituted of the gate electrodes 46, the gate insulating film 45 and the source and drain regions 44a and 44b are formed as shown in FIG. 12.

Results obtained by measuring the crystal orientation of a polycrystalline silicon film actually crystallized under the YAG laser irradiation conditions according to the second embodiment are now described with reference to FIG. 18. The crystal orientation of another polycrystalline silicon film crystallized under YAG laser irradiation conditions (scanning rate and power) 4 was also measured in addition to the polycrystalline silicon film actually crystallized under the YAG laser irradiation conditions according to the second embodiment. The conditions 4 are a scanning rate of about 400 mm/s and power of about 370 W respectively. The crystal orientations of the polycrystalline silicon films were measured through EBSPS. According to the second embodiment, the Mo film is irradiated with the YAG laser beam after the gate insulating film of SiO₂ and the Mo film (absorption film) are successively formed on the amorphous silicon film, and hence the gate insulating film and the Mo film must be removed in order to measure the crystal orientation of the polycrystalline silicon film through the EBSP. Therefore, the Mo film was removed with a mixed solution of nitric acid and ceric ammonium nitrate, and the gate insulating film of SiO₂ was thereafter removed with an HF (hydrogen fluoride) solution.

In each antipole figure shown in the lower half of FIG. 18, a laser scanning direction (SD) is a prescribed direction fixed in a substance or a space outside the substance, which is parallel to the YAG laser scanning direction. In each antipole figure shown in the upper half of FIG. 18, on the other hand, a film normal direction (ND) is the prescribed direction fixed in the substance or the space outside the substance, corresponding to the normal direction of a plane of the polycrystalline silicon film parallel to the main surface of a substrate. In each antipole figure shown in the lower half of FIG. 18, a portion held between broken lines in a basic triangle of a plane of stereographic projection is a region satisfying the following condition for setting the angle α formed by the crystal orientation <u v w> of the polycrystalline silicon film and twin planes to about 0° to about 10°:
|u−v−w|/(u²+v²+w²)^{1/2}≦0.3
Further, a region located above a thick line in the basic triangle of the plane of stereographic projection is that satisfying the following condition for setting the angle α formed by the crystal orientation <u v w> and the twin planes to about 0°:
u−v−w=0 (where u≧v≧w≧0)
In the basic triangle of the plane of stereographic projection shown in FIG. 18, further, a region hatched at smaller intervals can be classified as that having a large number of crystals having the orientation in the basic triangle, and a region hatched at larger intervals can be classified as that having a smaller number of crystals having the orientation than the region hatched at smaller intervals. In addition, an unhatched region in the basic triangle of the plane of stereographic projection shown in FIG. 18 is that hardly having crystals of the orientation. The abundance of crystals is expressed in an area ratio.

Referring to the antipole figures (lower half of FIG. 18) with reference to the YAG laser scanning direction (SD), it has been proved that a relatively large number of crystals are oriented in the region held between the broken lines under the YAG laser irradiation conditions (about 800 mm/s and about 530 W) according to the second embodiment. Referring to the antipole figured (upper half of FIG. 18) with reference to the normal direction (ND) of the plane of the polycrystalline silicon film parallel to the main surface of the substrate, it has been proved that no strong peak is present in the vicinity of the crystal orientation <1 1 1> (region in which the angle formed by the direction perpendicular to the main surface of the substrate and the crystal orientation <1 1 1> exceeds 10°) under the YAG laser irradiation conditions (about 800 mm/s and about 530 W) according to the second embodiment. Therefore, it can be said that a polycrystalline silicon film prepared under the YAG laser irradiation conditions according to the second embodiment has a large number of crystals having such orientational relation that the angle formed by the twin planes and the laser scanning direction (SD) is within about 10°.

According to the second embodiment, each channel region 44c is so formed that the carriers flowing through the channel region 44c flow in parallel with the YAG laser scanning direction, whereby deviation between the extensional direction of the twin planes formed on the polycrystalline silicon film 44 and the direction in which the carriers flow through the channel region 44c is generally within the range of about 100.

Referring to the antipole figures (lower half in FIG. 18) with reference to the YAG laser scanning direction (SD), it has been proved that a peak (region hatched at smaller intervals) is present in the vicinity of the thick line under the conditions 4 (about 400 mm/s and about 370 W) reduced in scanning rate as compared with the YAG laser irradiation conditions according to the second embodiment and also reduced in power in response thereto. This is conceivably because a time for fusing silicon was increased and a cooling rate was slowed down due to the slow scanning rate of the YAG laser beam.

Referring to the antipole figures (upper half in FIG. 18) with reference to the normal direction (ND) of the planes of the polycrystalline silicon films parallel to the main surfaces of the substrates, no peak was present in the vicinity of the crystal orientation <1 1 1> (region in which the angle formed by the direction perpendicular to the main surface of the substrate and the crystal orientation <1 1 1> exceeds 100) under the conditions 4, similarly to the YAG laser irradiation conditions according to the second embodiment. Therefore, it can be said that a polycrystalline silicon film prepared according to the conditions 4 has a larger number (area ratio) of crystals having such orientational relation that the angle formed by the twin planes and the laser scanning direction (SD) is within about 10°.

In the fabrication process according to the second embodiment, as hereinabove described, the Mo film (absorption film) 46a opposite to the quartz substrate 41 is irradiated with the YAG laser beam and scanned with the YAG laser beam when each polycrystalline silicon film 44 is formed by heating the amorphous silicon film 44f, whereby the amorphous silicon film 44f can be supplied with a large temperature gradient in crystallization similarly to the aforementioned first embodiment, dissimilarly to a case of entirely heating the amorphous silicon film 44f through an electric furnace or the like. Further, the crystal orientation of the polycrystalline silicon film 44 can be easily regulated by crystallizing the amorphous silicon film 44f from a low-temperature region toward a high-temperature region. When the amorphous silicon film 44f is so crystallized that the YAG laser scanning direction (SD) and the twin planes are approximately parallel to each other while carriers flow in parallel with the YAG laser scanning direction (SD), the carriers flowing through the channel region 44c can be easily inhibited from traversing the twin planes, similarly to the aforementioned first embodiment.

The remaining effects of the fabrication process according to the second embodiment are similar to those of the aforementioned first embodiment.

### Third Embodiment

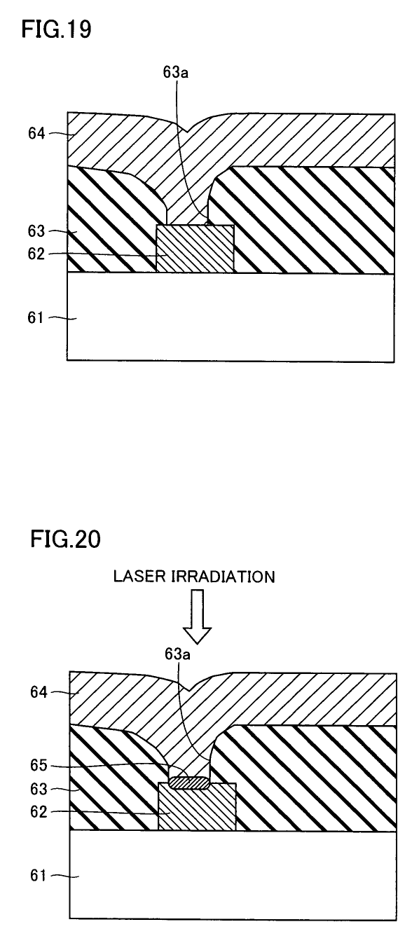

FIGS. 19 and 20 show a process of fabricating a semiconductor device according to a third embodiment of the present invention. Referring to FIGS. 19 and 20, crystal grain sizes of upper and lower wiring layers are increased by laser irradiation according to the third embodiment, dissimilarly to crystallization of the semiconductor layers according to the aforementioned first and second embodiments.

In the fabrication process according to the third embodiment, a film (lower wiring layer) 62 of Mo, which is high-melting point metal, having a thickness of about 50 nm to about 500 nm is formed on a prescribed region of a quartz substrate 61 by DC magnetron sputtering, and islanded. Thereafter an interlayer dielectric film 63 of SiO₂ or SiNₓ is formed by plasma CVD to cover the Mo film 62, and a contact hole 63a reaching the Mo film 62 is thereafter formed in the interlayer dielectric film 63. Another film (upper wiring layer) 64 of Mo, which is high-melting point metal, having a thickness of about 50 nm to about 250 nm is formed on the interlayer dielectric film 63 by DC magnetron sputtering, to be connected to the Mo film 62 through the contact hole 63a. The Mo films 62 and 64, partially forming metal wires in a thin-film transistor substrate (TFT substrate), for example, correspond to a gate electrode wire and a data wire respectively.

Then, the structure shown in FIG. 19 is preheated under a temperature condition of about 300° C. Thereafter the Mo film 64 is irradiated with a continuous-wave Nd:YAG laser beam (wavelength: 1064 nm) condensed in the form of a rectangle of about 0.1 mm by about 3 mm and scanned in the short-side direction of the Nd:YAG laser beam in an Ar gas atmosphere, as shown in FIG. 20. The irradiation conditions for the ND:YAG laser beam are a scanning rate of about 700 mm, beam intensity of about 300 W and defocusing of ±0 m.

At this time, the Mo film 64 serving as the upper wiring layer is so heated that the crystal grain size thereof is increased beyond that before laser irradiation. Further, the Mo film 64 serving as the upper wiring layer generates heat, for heating the Mo film 62 serving as the lower wiring layer with this heat. Thus, the crystal gain size of the Mo film 62 serving as the lower wiring layer is also increased beyond that before laser irradiation. A self-diffusion layer 65 is formed on the interface between the Mo films 62 and 64 serving as the lower and upper wiring layers respectively.

According to the third embodiment, as hereinabove described, the Mo film 62 serving as the lower wiring layer is formed on the quartz substrate 61 while the Mo film 64 serving as the upper wiring layer is formed to be connected to the Mo film 62 through the contact hole 63a and the Mo film 64 is thereafter irradiated with the Nd:YAG laser beam so that the crystal grain sizes of the Mo films 62 and 64 are increased beyond those before laser irradiation, whereby sheet resistance values of the Mo films 62 and 64 can be reduced beyond those before laser irradiation. Further, the self-diffusion layer 65 is formed on the interface between the Mo films 62 and 64 serving as the lower and upper wiring layers respectively, whereby adhesiveness between the Mo films 62 and 64 can be improved. Thus, contact resistance between the Mo films 62 and 64 can be reduced. In addition, the Mo film 64 serving as the upper wiring layer formed to be connected to the Mo film 62 through the contact hole 63a is so irradiated with the Nd:YAG laser beam that the portion of the Mo film 64 located in the contact hole 63a easily causing voids can be densified. Thus, the resistance of the portion of the Mo film 64 located in the contact hole 63a can be reduced.

When the Mo film 64 serving as the upper wiring layer requires patterning, the Mo film 64 is preferably irradiated with the Nd:YAG laser beam before patterning. Thus, instability of temperatures on ends of the Mo film 64 irradiated with the Nd:YAG laser beam can be so avoided that the processing can be stably performed.

An experiment performed for confirming the effect attained by increasing the crystal grain size among the effects of the aforementioned third embodiment is now described.

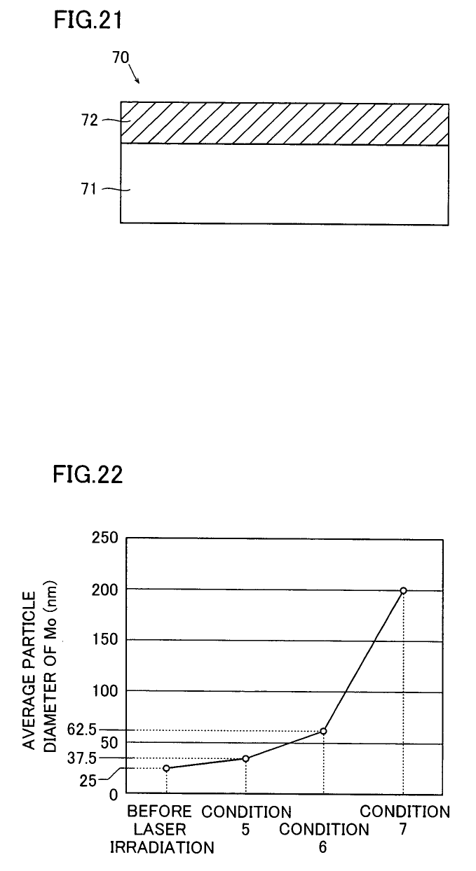

First, a sample 70 shown in FIG. 21 was prepared. More specifically, a film 72 of Mo, which is high-melting point metal, having a thickness of about 50 nm was formed on a discoidal quartz substrate 71 having a diameter of about 150 mm by DC magnetron sputtering under conditions of atmosphere gas of Ar gas, a gas pressure of about 0.6 Pa, power of about 480 W, a film forming time of about 48 s and a substrate temperature of about 100° C. Thus, the sample 70 having the Mo film 72 formed on the quartz substrate 71 was prepared.

Thereafter the sample 70 prepared in the aforementioned manner was irradiated with a laser beam, for increasing the crystal grain size of the Mo film 72. More specifically, the sample 70 was preheated under a temperature condition of about 300° C., and the Mo film 72 was irradiated with a continuous-wave Nd:YAG laser beam (wavelength: 1064 nm) condensed in the form of a rectangle of about 0.1 mm by about 3 mm in an Ar gas atmosphere and scanned in the short-side direction of the Nd:YAG laser beam.

At this time, three Mo films 72 were irradiated with laser beams under three different irradiation conditions 5 to 7, for measuring crystal grain sizes and sheet resistance values of the Mo films 72 processed under the irradiation conditions 5 to 7 respectively. The irradiation conditions 5 are a scanning rate of about 1000 mm/s, beam intensity of about 490 W and defocusing of +600 μm. The irradiation conditions 6 are a scanning rate of about 700 mm/s, beam intensity of about 300 W and defocusing of ±0 μm. The irradiation conditions 7 are a scanning rate of about 700 mm/s, beam intensity of about 410 W and defocusing of ±0 μm.

The maximum processing temperatures under the irradiation conditions 5 to 7 conceivably reach about 900° C., about 1700° C. and about 2200° C. respectively. The term “maximum processing temperature” indicates the sum of the initial temperature (about 300° C.) and heating temperature difference (ΔT), which was obtained according to the following formula (1):
P=(π/4ε)·p·c·W·ΔT·(2α·L·v)^{1/2} (1)
where α=κ/(ρ·c), P represents the beam intensity (W (watts)), p represents the density (kg/m³), c represents the specific heat (J/kg·K), W represents the beam width (width in the direction perpendicular to the scanning direction, m), a represents the temperature transfer factor (m²/s), L represents the beam length (length in the scanning direction, m), v represents the scanning rate (m/s) and κ represents the thermal conductance (J/m·K·s). Further, ε represents the irradiation efficiency including the efficiency of a transmission system, the efficiency of a lens, the reflectance on the surface of each sample etc. The irradiation efficiency ε was empirically set to about 0.195. The thermal conductance κ, the density ρ and the specific heat c are about 1.37 J/m·K·s, about 2200 kg/M³ and about 740 J/m·K·s respectively.

FIG. 22 shows the relation between the laser irradiation conditions and the crystal grain sizes. Referring to FIG. 22, it has been proved that the crystal grain sizes were increased due to laser irradiation beyond those (about 25 nm) before laser irradiation. It has also been proved that the crystal grain sizes were increased as the maximum processing temperatures were increased. More specifically, the crystal grain sizes of the Mo films 72 processed according to the irradiation conditions 5, 6 and 7 (about 900° C., about 1700° C. and about 2200° C.) respectively were about 37.5 nm, about 62.5 nm and about 200 nm respectively. It is conceivable from these results that the crystal grain size of the Mo film 72 can be further increased by setting laser irradiation conditions to increase the maximum processing temperature.

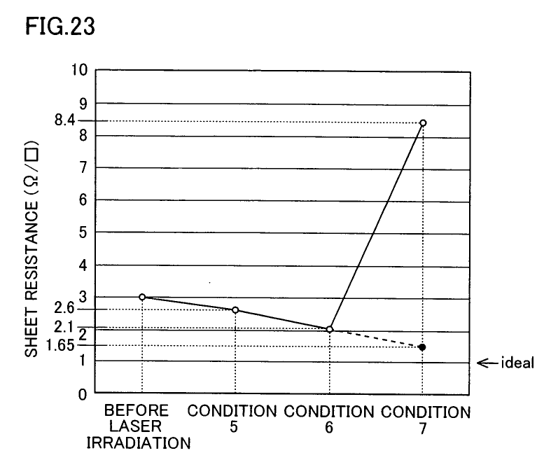

FIG. 23 shows the relation between the laser irradiation conditions and the sheet resistance values. The sheet resistance values were measured by a four-point probe method. Referring to the axis of ordinates of FIG. 23, “ideal” denotes an ideal sheet resistance value (about 1 Ω/ [symbol] ) calculated from the specific resistance of Mo in a bulk state. Referring to FIG. 23, the sheet resistance values of the Mo films 72 were about 3 Ω/ [symbol] before laser irradiation. The Mo films 72 processed under the irradiation conditions 5 and 6 respectively exhibited sheet resistance values of about 2.6 Ω/ [symbol] and about 2.1 Ω/ [symbol] respectively. In other words, it has been proved that the sheet resistance values of the Mo films 72 processed according to the irradiation conditions 5 and 6 more approached to the ideal value (about 1 Ω/ [symbol] ) as compared with the sheet resistance values (about 3 Ω/ [symbol] ) before laser irradiation.

In the fabrication process according to the third embodiment shown in FIG. 20, the Mo film 64 is irradiated with the laser beam under the conditions (scanning rate of about 700 mm/s, beam intensity of about 300 W and defocusing of +0 μm) similar to the irradiation conditions 6, whereby it can be said that the sheet resistance of the Mo film 62 can approach to the ideal value.

On the other hand, the sheet resistance value (about 8.4 Ω/ [symbol] ) of the Mo film 72 processed according to the irradiation conditions 7 was remarkably increased beyond the ideal value (about 1 Ω/ [symbol] ). When the Mo film 72 processed according to the irradiation conditions 7 was observed with a TEM (transmission electron microscope), small cracks were formed along crystal boundaries. This is conceivably because stress caused on the interface between the quartz substrate 71 having a thermal expansion coefficient of substantially zero and the Mo film 72 was increased in cooling after laser irradiation due to the extremely high maximum processing temperature (about 2200° C.) according to the irradiation conditions 7.

In this experiment, therefore, another Mo film 72 was formed on a substrate of no alkali glass, having a thermal expansion coefficient close to that of the Mo film 72, employed in place of the quartz substrate 71 and processed according to the irradiation conditions 7, to be subjected to measurement of sheet resistance. In this case, beam intensity was set to about 375 W, so that the maximum processing temperature was 2200° C. equally to that under the irradiation conditions 7. As a result of this measurement, the sheet resistance value of the Mo film 72 processed according to the irradiation conditions 7 was about 1.65 Ω/ [symbol] (black circle in FIG. 23). In other words, it has been proved that the sheet resistance value of the Mo film 72 processed according to the irradiation conditions 7 more approached to the ideal value (1 Ω/ [symbol] ) as compared with the sheet resistance values (about 2.6 Ω/ [symbol] and about 2.1 Ω/ [symbol] ) of the Mo films 72 processed according to the irradiation conditions 5 and 6 respectively.

Although the present invention has been described and illustrated in detail, it is clearly understood that the same is by way of illustration and example only and is not to be taken by way of limitation, the spirit and scope of the present invention being limited only by the terms of the appended claims.

For example, while the plurality of n-type thin-film transistors are formed on the substrate in each of the aforementioned first and second embodiments, the present invention is not restricted to this but a plurality of p-type thin-film transistors may alternatively be formed on the substrate. Further alternatively, a plurality of n-type thin-film transistors and a plurality of p-type thin-film transistors may be formed on the substrate.

While the films of Mo, which is high-melting point metal, are employed as the wiring layers in the aforementioned third embodiment, the present invention is not restricted to this but films of Cr, Ta, W or Ti, which is high-melting point metal, may alternatively be employed as wiring layers in place of the Mo films. Further alternatively, films of Al or Cu having a relatively low melting point may be employed as wiring layers. Further alternatively, films of an oxide conductor such as ITO (indium tin oxide) or IZO (indium zinc oxide) may be employed as wiring layers. In addition, the wiring layers may be employed as gate wires, data wires (source/drain wires), power supply lines or gate electrodes of thin-film transistors.

1. A semiconductor device comprising:
a substrate; and
a plurality of semiconductor elements, formed on said substrate, each including a semiconductor layer having a channel region with carriers flowing in a first direction, wherein
said semiconductor layer constituting each of said plurality of semiconductor elements has a twin plane, and said twin plane is formed to extend in such a second direction that said carriers flowing through said channel region hardly traverse said twin plane.

2. The semiconductor device according to claim 1, wherein
said twin plane is formed to extend in a direction substantially parallel to said first direction in which said carriers flow through said channel region.

3. The semiconductor device according to claim 1, wherein
said semiconductor layer has a face-centered cubic lattice crystal structure, and
a crystal orientation <u v w> in said first direction satisfies the following two formulas:
u−v−w|/(u²+v²+w²)^{1/2}≦0.3
u≧v≧w≧0
assuming that said crystal orientation <u v w> corresponds to said first direction in which said carriers in said semiconductor layer flow through said channel region and an angle formed by a direction perpendicular to the main surface of said substrate and a crystal orientation <1 1 1> exceeds about 10°.

4. The semiconductor device according to claim 1, wherein
said semiconductor layer has a plurality of said twin planes, and
said plurality of twin planes are formed to extend substantially in the same direction.

5. The semiconductor device according to claim 1, further comprising an insulating film formed between said substrate and said semiconductor layer to be in contact with said semiconductor layer with a contact angle of not more than about 45° with fused said semiconductor layer.

6. The semiconductor device according to claim 1, wherein
said semiconductor layer includes a polycrystalline silicon film.

7. The semiconductor device according to claim 1, wherein
said semiconductor layer includes an active layer of a thin-film transistor.

8. A method of fabricating a semiconductor device, comprising steps of:
forming a semiconductor layer serving as an active layer of each of a plurality of semiconductor elements on a substrate;
crystallizing said semiconductor layer to have a twin plane extending in a prescribed direction; and
forming a channel region on said semiconductor layer so that carriers flowing in a channel length direction hardly traverse said twin plane extending in said prescribed direction.

9. The method of fabricating a semiconductor device according to claim 8, wherein
said step of forming said channel region includes a step of forming said channel region so that said twin plane extending in said prescribed direction and said channel length direction in which said carriers flow are substantially parallel to each other.

10. The method of fabricating a semiconductor device according to claim 8, wherein
said step of crystallizing said semiconductor layer includes a step of crystallizing said semiconductor layer so that each of a plurality of said twin planes extends in said prescribed direction.

11. The method of fabricating a semiconductor device according to claim 8, wherein
said step of crystallizing said semiconductor layer includes a step of supplying a temperature gradient to said semiconductor layer and crystallizing said semiconductor layer from a low temperature region toward a high temperature region in said temperature gradient.

12. The method of fabricating a semiconductor device according to claim 8, wherein
said step of crystallizing said semiconductor layer includes a step of crystallizing said semiconductor layer to have said twin plane extending in said prescribed direction by scanning said semiconductor layer with a laser beam thereby heating said semiconductor layer.

13. The method of fabricating a semiconductor device according to claim 12, wherein
said laser beam has a rectangular shape, and
said step of crystallizing said semiconductor layer includes a step of crystallizing said semiconductor layer to have said twin plane extending in said prescribed direction by scanning said semiconductor layer with said laser beam in the short-side direction of said laser beam thereby heating said semiconductor layer.

14. The method of fabricating a semiconductor device according to claim 12, wherein
said step of forming said channel region includes a step of forming said channel region so that said carriers flow in a direction substantially parallel to the scanning direction of said laser beam.

15. The method of fabricating a semiconductor device according to claim 12, further comprising a step of forming an absorption film on said substrate, wherein
said step of crystallizing said semiconductor layer includes a step of irradiating said absorption film with said laser beam thereby making said absorption film generate heat and crystallizing said semiconductor layer through said heat.

16. The method of fabricating a semiconductor device according to claim 15, wherein
said step of forming said absorption film includes a step of forming said absorption film between said substrate and said semiconductor layer, and
said step of crystallizing said semiconductor layer includes a step of irradiating said absorption film with said laser beam from the side of said substrate thereby making said absorption film generate heat and crystallizing said semiconductor layer through said heat.

17. The method of fabricating a semiconductor device according to claim 15, wherein
said step of forming said absorption film includes a step of forming said absorption film on said semiconductor layer, and
said step of crystallizing said semiconductor layer includes a step of directly irradiating said absorption film with said laser beam thereby making said absorption film generate heat and crystallizing said semiconductor layer through said heat.

18. The method of fabricating a semiconductor device according to claim 12, wherein
said laser beam includes a continuous-wave laser beam.

19. The method of fabricating a semiconductor device according to claim 8, further comprising a step of forming an insulating film having a contact angle of not more than about 45° with fused said semiconductor layer on said substrate, wherein
said step of forming said semiconductor layer includes a step of forming said semiconductor layer on said insulating film to be in contact with said insulating film.

20. The method of fabricating a semiconductor device according to claim 8, wherein
said semiconductor layer includes a silicon film, and
said step of crystallizing said semiconductor layer includes a step of crystallizing an amorphous silicon film into a polycrystalline silicon film.

21. The method of fabricating a semiconductor device according to claim 8, wherein
said semiconductor layer includes a semiconductor layer serving as an active layer of a thin-film transistor.
